(19) United States
(12) Patent Application Publication
(10) Pub. No.: US 2020/0051812 A1
(43) Pub. Date: Feb. 13, 2020

(54) PREVENTING DELAMINATION AT SILICON/DIELECTIC INTERFACE

(71) Applicant: International Business Machines Corporation, Armonk, NY (US)

(72) Inventors: Michael P. Belyansky, Halfmoon, NY (US); Brock J. Mendoza, Troy, NY (US); Richard A. Conti, Altamont, NY (US); Yong Liang, Niskayuna, NY (US); Han You, Cahoes, NY (US)

(21) Appl. No.: 16/056,811

(22) Filed: Aug. 7, 2018

(51) Int. Cl. H01L 21/02; H01L 21/8238

(52) U.S. Cl. CPC H01L 21/02274; H01L 21/02211; H01L 21/823878; H01L 21/823821; H01L 21/02164

(57) ABSTRACT

A method for fabricating a semiconductor device includes: forming a plurality of fins from a substrate, the fins including nFET fins and pFET fins; forming a trench between the nFET fins and pFET fins; forming a silicon nitride (SiN) layer over the trench, the nFET fins and the pFET fins to create an intermediate device; and depositing with a high density plasma (HDP) process an HDP layer of silicon dioxide (SiO₂) over the trench, the nFET fins and the pFET fins. The HDP process includes loading the intermediate device into a deposition chamber and introducing hydrogen (H₂) gas and silane (SiH₄) into the deposition chamber, wherein the H₂ gas is not introduced into the deposition chamber before the SiH₄ is introduced into the deposition chamber.

### BACKGROUND

The present invention generally relates to fabrication methods and resulting structures for semiconductor devices. More specifically, the present invention relates to a method of addressing delamination between a silicon substrate and a dielectric in FinFET devices.

CMOS technology is used to construct integrated circuits such as microprocessors, microcontrollers, static random access memory (RAM) and other digital logic circuits. A basic component of CMOS designs is metal oxide semiconductor field effect transistors (MOSFETs).

A FinFET is a type of MOSFET. The FinFET is a double-gate or multiple-gate MOSFET device that mitigates the effects of short channels and reduces drain-induced barrier lowering. The term “fin” refers to the narrow channel between source and drain regions. Fins are typically formed from the silicon substrate on which the MOSFET is formed.

FinFET devices are fabricated by forming a set of fins on a substrate. Depending on device design, the number of fins varies from an array of multiple fins to an “isolated” single fin devices. The fins/devices are separated by shallow trench isolation (STI) recesses in the substrate (or STI regions), which are filled with a dielectric oxide.

### SUMMARY

One embodiment of the present invention is directed to a method for fabricating a semiconductor device is disclosed. The method of this embodiment includes: forming a plurality of fins from a substrate, the fins including nFET fins and pFET fins; forming a trench between the nFET fins and pFET fins; forming a silicon nitride (SiN) layer over the trench, the nFET fins and the pFET fins to create an intermediate device; and depositing with a high density plasma (HDP) process an HDP layer of silicon dioxide (SiO₂) over the trench, the nFET fins and the pFET fins. The HDP process includes loading the intermediate device into a deposition chamber and introducing hydrogen (H₂) gas and silane (SiH₄) into the deposition chamber, wherein the H₂ gas is not introduced into the deposition chamber before the SiH₄ is introduced into the deposition chamber.

In another embodiment, a fabricating a semiconductor device includes: forming a plurality of fins from a substrate, the fins including nFET fins and pFET fins separated from one another; forming a silicon nitride (SiN) layer over the nFET fins and the pFET fins; forming a liner layer of SiO₂ over the SiN layer with a non-HDP process to create an intermediate device; and depositing with a HDP process a HDP layer of SiO₂ over the SiN layer. The HDP process includes loading the intermediate device into a deposition chamber and introducing hydrogen (H₂) gas and silane (SiH₄) into the deposition chamber, wherein the H gas is not introduced into the deposition chamber before the SiH₄ is introduced into the deposition chamber.

In another embodiment, a method of fabricating a semiconductor device includes forming a plurality of fins from a substrate, the fins including nFET fins and pFET fins; forming a trench between the nFET fins and pFET fins, the trench including one or more fins; forming a silicon nitride (SiN) layer over the trench, the nFET fins and the pFET fins; forming a liner layer of SiO₂ over the SiN layer with a non-high density plasma (HDP) process to create an intermediate device; and depositing with a high density plasma (HDP) process a HDP layer of silicon dioxide (SiO₂) over the trench, the nFET fins and the pFET fins. The HDP process includes loading the intermediate device into a deposition chamber and introducing hydrogen (H₂) gas and silane (SiH₄) into the deposition chamber, wherein the H₂ gas is not introduced into the deposition chamber before the SiH₄ is introduced into the deposition chamber.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a semiconductor structure after a fabrication operation according to embodiments of the invention;

FIG. 2 depicts the semiconductor structure/device according to embodiments of the invention after formation of fins from the substrate;

FIG. 3 depicts the semiconductor device according to embodiments of the invention after an isolation trench has been formed in the substrate;

FIG. 4 depicts the semiconductor device according to embodiments of the invention after a layer silicon nitrite has been added over the device of FIG. 3;

FIG. 5 depicts the semiconductor device according to embodiments of the invention deposition of a thin oxide layer and an oxide layer deposited by a high density plasma (HDP) process have been formed over the device of FIG. 4;

FIG. 6 depicts the semiconductor device according to embodiments of the invention deposition of a thin oxide layer and an oxide layer deposited by a high density plasma (HDP) process have been formed over the device of FIG. 4;

FIG. 7 depicts the semiconductor device of FIG. 6 that includes fins formed in the trench region; and

FIG. 8 depicts the semiconductor device of FIG. 5 that includes fins formed in the trench region.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The phrase “semiconductor device” and variations thereof, are used in this detailed description to include any completed device or workpiece created during the formation of a completed device that can exploit the electronic properties of semiconductor materials. Example semiconductor devices include but are not limited to transistors and diodes.

Turning now to an overview of technologies that are more specifically relevant to aspects of the invention, High Density Plasma (HDP) silicon oxide (SiO₂) is a dense, stable oxide desirable for STI fill, gap-fill, and other applications. In the case of FinFET devices, it is known that a thin liner is typically needed between a silicon substrate and the HDP SiO₂ to prevent oxidation of the fin during deposition of the HDP SiO₂. One type of liner that is typically used is formed of silicon nitride (SiN).

It has been discovered, however, that in the STI region or other large silicon surfaces, compressive stress from HDP SiO₂, together with large amount of hydrogen and plasma damage on SiN during initial HDP deposition result in severe delamination in Si/SiN/HDP-SiO₂ stack or Si/SiO₂/SiN/HDP-SiO₂ stack, often at Si/SiN interface (for Si/SiN/HDP-SiO₂ stack) or at SiO₂/SiN interface (for Si/SiO₂/SiN/HDP-SiO₂ stack).

Disclosed herein are two different approaches to reducing delamination. The two approaches can be used separately or in combination. The first manner in which delamination at Si/SiN can be overcome is by adding a protective thin, conformal, low direct-plasma based SiO₂ layer on top of the SiN liner layer by using a process such as atomic layer deposition (ALD). In this approach, an optional rapid thermal annealing process may be performed and then the HDP SiO₂ deposition is performed.

In the second approach, regardless of whether the ALD SiO₂ is provided, the process hydrogen in deposition chamber is reduced/eliminated during the temperature ramp prior to the HDP SiO₂ deposition. This can be accomplished, in one embodiment, by ensuring that little or no hydrogen is provided during the HDP SiO₂ deposition prior to introduction of silane (SiH₄) into the deposition chamber.

Further, in combination with one or both of the above approaches, dummy fins can be introduced into the STI region.

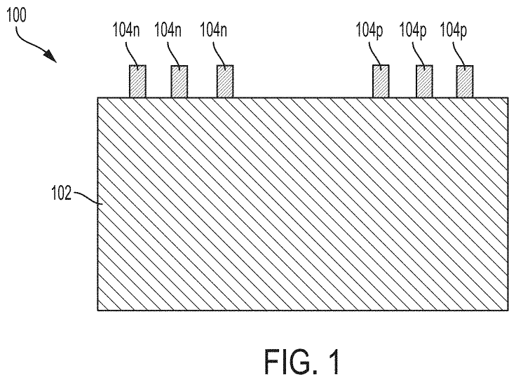

FIG. 1 illustrates a cross-sectional view of a structure 100 having a substrate 102 during an intermediate operation of a method of fabricating a semiconductor device according to one or more embodiments.

The substrate 102 can be of any suitable substrate material such as, for example, monocrystalline Si, SiGe, SiC, or semiconductor-on-insulator (SOI). In some embodiments, a top layer of the substrate 102 can be Si, SiGe, Group III-V channel material, or other suitable channel materials. Group III-V channel materials include materials having at least one group III element and at least one group V element, such as, for example, one or more of aluminum gallium arsenide, aluminum gallium nitride, aluminum arsenide, aluminum indium arsenide, aluminum nitride, gallium antimonide, gallium aluminum antimonide, gallium arsenide, gallium arsenide antimonide, gallium nitride, indium antimonide, indium arsenide, indium gallium arsenide, indium gallium arsenide phosphide, indium gallium nitride, indium nitride, indium phosphide and alloy combinations including at least one of the foregoing materials.

In some embodiments, a hardmask layer is deposited on top of the substrate 102 and patterned such that discrete hardmasks 104 remain. The hardmasks can be of any suitable material, such as silicon nitride SiN and can be referred to herein as a fin hardmask from time to time. In more detail, the fins are formed by forming fin hardmasks 104 on top of a substrate 102 and then performing a reactive ion etching process on the substrate to remove portions of the substrate not covered by the fin hardmask layer 104. Because there is no stop layer on or in the substrate 102, the reactive ion etch process is time based.

As illustrated, the hardmasks 104 are labelled as 104n and 104p. This is to denote that the device 100 can, when completed, form a CMOS FinFET device having an nMOS (with fins 104n) and a pMOS (with fins 104p). It will be understood, however, that the teachings herein are not limited to such an application and can be utilized in any situation where HDP SiO₂ is formed on SiN.

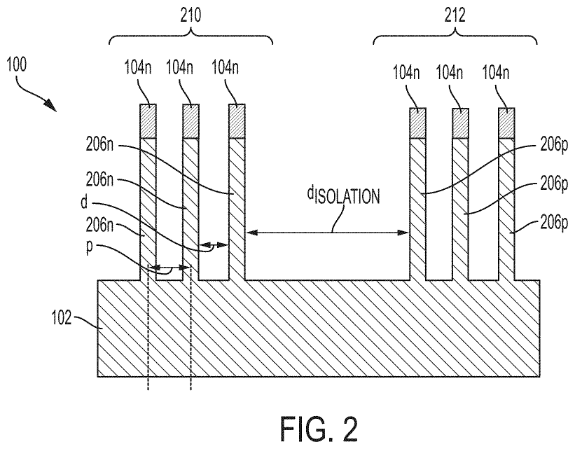

FIG. 2 illustrates a cross-sectional view of the structure 100 after the formation of fins for the nFET (206n) and fins for the pFET (206p). These fins can be referred to in groups referred to as the nFET fin group 210 and the pFET fin group 212. The fins can be formed by lithography or etching. The lithography can be for example, self-aligned double patterning (SADP) or self-aligned quadruple patterning (SAQP).

The center of each fin 206n, 206p is separated from the center of it nearest neighbor by a distance p or “fin pitch”. Of course the distance p could be measured from one left edge of a fin to the left edge of its adjacent neighbor in some embodiments. For a particular fin pitch, a distance “d” exists between each adjacent fin. This space between adjacent fins in particular, fin group 210, 212 can be referred to as a gap.

As illustrated, the nFET fin group 110 is separated from the pFET fin group 112 by an isolation distance dᵢₛₒₗₐₜᵢₒₙ.

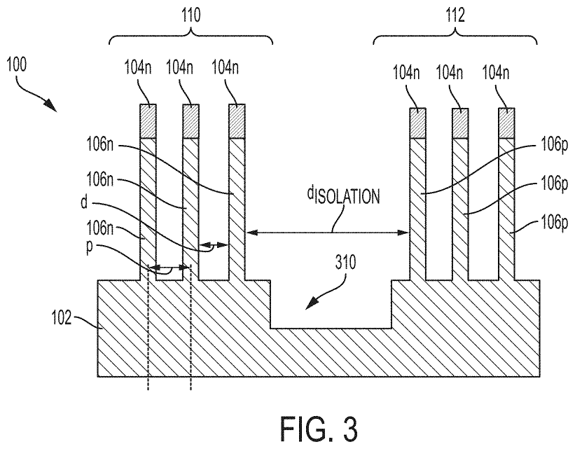

As shown in FIG. 3, a shallow trench isolation trench 310 can be formed in a conventional manner. In many instances, the trench 310 is typically filled by HDP SiO₂ deposition. The gaps between adjacent fins 106n,106p is can also be filled by HDP SiO₂ deposition. This trench 310 is optional and can be omitted.

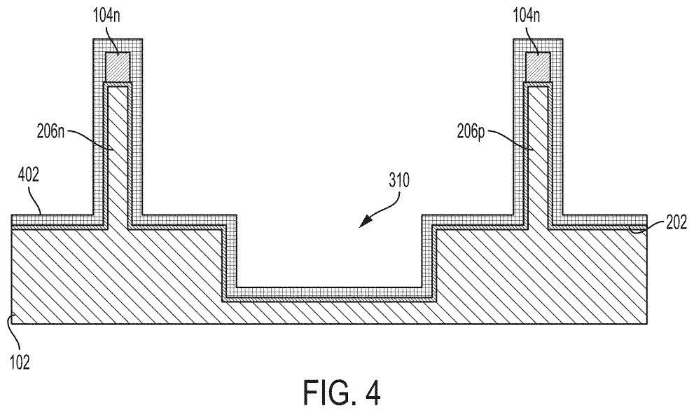

As discussed above, in one embodiment, before the HDP SiO₂ deposition is performed, and a shown in FIG. 4, a SiN layer 402 is conformably deposited over the fins 106n, 106p and on the trench 310. As illustrated in FIG. 4 an optional oxide interface layer 202 is located between the substrate 102 and the SiN liner 402. This layer may be referred to as an interface layer and can be formed of SiO₂ in one embodiment. In FIG. 4, only a single nFET fin 206n and a single pFET fin 206p is shown for simplicity. However, the steps shown in FIG. 4 and following figures can be applied to multiple fin finFETS formed, for example, with the process steps shown in FIGS. 1-3. The different approaches taken in the following FIGs. address the delamination that occurs at the junction between the SiN layer 402 and the silicon substrate 102. While such delamination can happen at any location it has been discovered that such delamination is more likely to occur in a region with a large, flat region of exposed silicon such as that in trench 310. The critical width of an isolation region (dᵢₛₒₗₐₜᵢₒₙ of FIG. 3) where the delamination defect starts to occur is typically about 0.25 micron or larger. Only devices that have a very narrow isolation region (less than 0.1 micron) are typically safe from this type of defect due to small surface area that prevents large stress build up and limits the amount of hydrogen that bubbles out of the structure during HDP oxide deposition and anneals. These two effects are believed to be the main causes behind the loss of adhesion. Therefore, embodiments herein may focus on devices separated by a larger isolation region with dᵢₛₒₗₐₜᵢₒₙ width more than 0.2-0.3 micron.

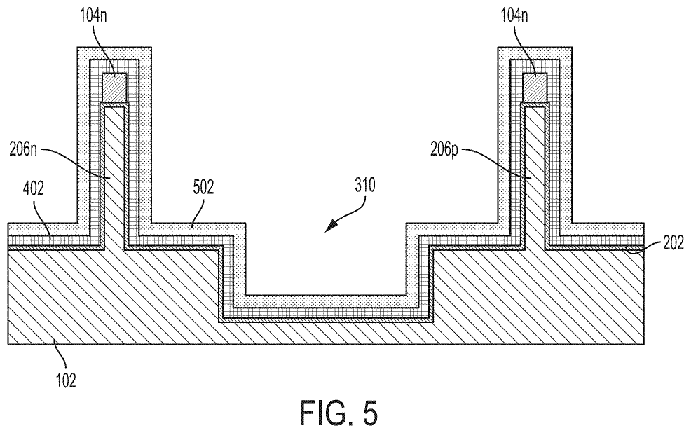

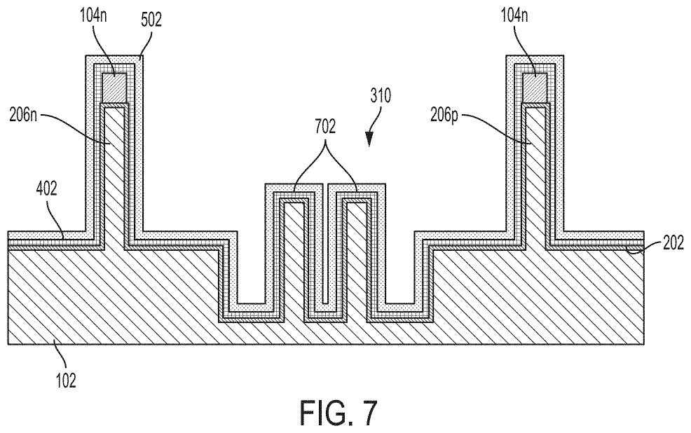

FIG. 5 shows the device 100 of FIG. 5 after the deposition of HDP SiO₂ layer 502. The layer 602 can be deposited by a conventional technique in one embodiment. In another embodiment, the layer 502 is deposited in the manner described in relation to FIG. 7 where hydrogen is reduced/eliminating during temperature ramp up prior to HDP deposition.

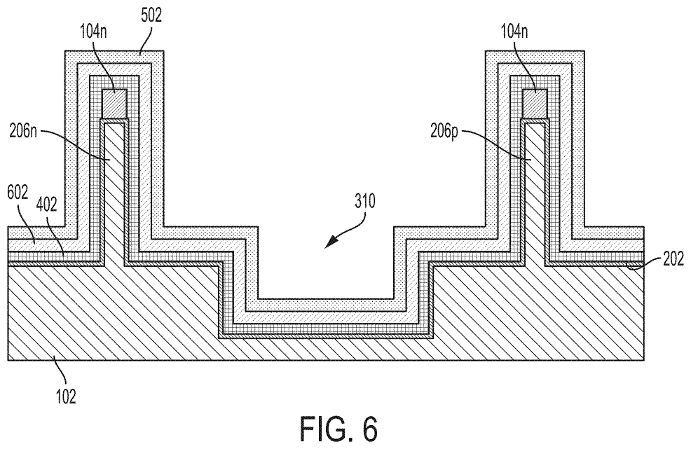

FIG. 6 shows the device 100 after, according to one embodiment, deposition of a thin, conformal, non-direct-plasma deposited SiO₂ liner layer 602 is deposited on the SiN layer 402. The deposition can be by ALD, or other conformal SiO₂ film CVD films such as high aspect ratio process (HARP®) CVD film by Applied Materials, etc.

As shown in FIG. 5, this SiO₂ liner layer 502 is deposited before the HDP SiO₂ deposition is performed. The device 100 of FIG. 5 can optionally be exposed to a rapid thermal annealing process.

In general, HDP SiO₂ deposition typically includes the following steps:

1) Load the device 100 into a deposition chamber;
2) Flow Argon gas and start the plasma source;
3) Heat up device 100 in the chamber;
4) Introduce hydrogen gas and stabilize the temperature and the plasma;
5) Introduce SiH₄ and oxygen gases, increase plasma power, start SiO₂ deposition;
6) Stop film deposition by stopping SiH₄ and hydrogen gas flow, reduce plasma power;
7) Cool down device; and
8) Unload device from the deposition chamber.

The addition of the SiO₂ liner layer 502 before this HDP SiO₂ process has been shown to reduce delamination between the SiN layer 402 and the silicon substrate that is at least partly due to the performance of the HDP SiO₂ process. One possible reason is that the SiO₂ liner layer 502 may reduce plasma damage to the SiN layer 402, which may weaken the interface process as the HDP plasma ambient provides ionized species that attack the nitride due to ion bombardment, and highly reactive species such as ionized H can penetrate the nitride layer.

According to one embodiment, the HDP process can be changed. The alternative process can the following steps:

1) Load the device 100 into a deposition chamber;
2) Flow Argon gas and start the plasma source;
3) Heat up device 100 in the chamber;
4) Stabilize the temperature and the plasma. This step can happen without hydrogen flow;
5) Introduce SiH₄ and hydrogen and oxygen gases, increase plasma power, start SiO₂ deposition;
6) Stop film deposition by stopping SiH₄ and hydrogen gas flow, reduce plasma power;
7) Cool down wafer; and
8) Unload device from the deposition chamber.

From the above, it is clear that the newly described process can be performed in such a manner that hydrogen gas is not introduced into the deposition chamber until the same time or after the introduction of SiH₄ into the chamber during the HDP plasma SiO₂ deposition.

In an alternative embodiment to that described in relation to FIG. 5, as shown in FIG. 6, the HDP plasma SiO₂ layer 602 is deposited without first having the SiO₂ liner layer 502 of FIG. 5 provided. In this embodiment, the HDP plasma SiO₂ layer 602 is deposited according to the alternative process described immediately above where hydrogen gas is not introduced into the deposition chamber until the same time or after the introduction of SiH₄ into the chamber during the HDP plasma SiO₂ deposition such that deposition of SiO₂ has begun before or at the same time at which hydrogen is introduced.

As shown in FIG. 7 and relevant to FIG. 5, according to one embodiment, one or more trench fins 702 can be formed in the trench or other flat region to further help reduce delamination by breaking propagation and aggregation. As shown in FIG. 7, the fins 702 can be used in a process that excludes the SiO₂ liner layer 602. The placement of fins in the isolation area is to shorten the available flat area to less than 0.1 micron, in order to reduce the probability of adhesion loss and due to less flat area available for hydrogen outgassing and strain build up above. Chopping the isolation region by fin placement at least every 0.1 micron or less, ensures better adhesion of all major interfaces like Si/SiN or SiO₂/SiN.

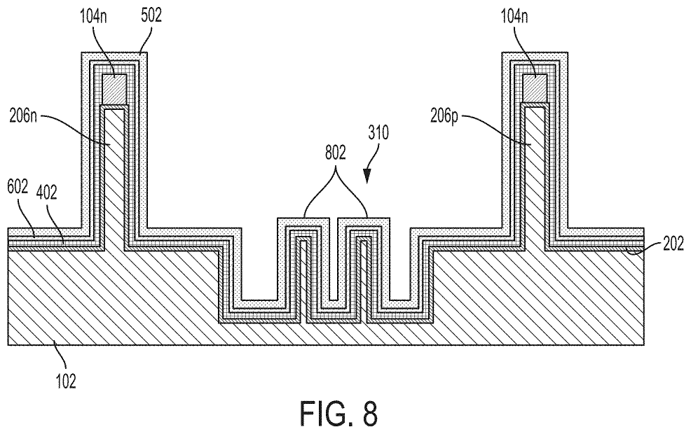

As shown in FIG. 8 and relevant to both FIG. 6, according to one embodiment, one or more trench fins 802 can be formed in the trench or other flat region to further help reduce delamination by breaking propagation and aggregation. As shown in FIG. 8, fins 802 can be used with a process that includes the SiO₂ liner layer 602.

Of course, any of the devices formed in FIGS. 5-8 could undergo further processing to form source and drain regions and one or more gates to form, for example, a CMOS device. Such further processing can be selected based on the needs of the final device.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of fabricating a semiconductor device, the method comprising:
forming a plurality of fins from a substrate, the fins including nFET fins and pFET fins;
forming a trench between the nFET fins and pFET fins;
forming a silicon nitride (SiN) layer over the trench, the nFET fins and the pFET fins to create an intermediate device; and
depositing with a high density plasma (HDP) process an HDP layer of silicon dioxide (SiO₂) over the trench, the nFET fins and the pFET fins;
wherein the HDP process includes loading the intermediate device into a deposition chamber and introducing hydrogen (H₂) gas and silane (SiH₄) into the deposition chamber, wherein the H₂ gas is not introduced into the deposition chamber before the SiH₄ is introduced into the deposition chamber.

2. The method of claim 1, wherein the H₂ gas is introduced into the deposition chamber at the same time the SiH₄ is introduced into the deposition chamber.

3. The method of claim 1, wherein the H₂ gas is introduced into the deposition chamber after the SiH₄ is introduced into the deposition chamber.

4. The method of claim 1 further comprising: forming a silicon oxide interface layer over the substrate before depositing the SiN layer.

5. The method of claim 4 further comprising annealing the intermediate device after forming the liner layer of SiO₂.

6. The method of claim 1, wherein forming the trench includes forming fins in the trench.

7. A method of fabricating a semiconductor device, the method comprising:
forming a plurality of fins from a substrate, the fins including nFET fins and pFET fins separated from one another;
forming a silicon nitride (SiN) layer over the nFET fins and the pFET fins;
forming a liner layer of silicon dioxide (SiO₂) over the SiN layer with a non-high density plasma (HDP) process to create an intermediate device; and
depositing with a HDP process a HDP layer of SiO₂ over the SiN layer;
wherein the HDP process includes loading the intermediate device into a deposition chamber and introducing hydrogen (H₂) gas and silane (SiH₄) into the deposition chamber, wherein the H₂ gas is not introduced into the deposition chamber before the SiH₄ is introduced into the deposition chamber.

8. The method of claim 7, wherein the H₂ gas is introduced into the deposition chamber at the same time the SiH₄ is introduced into the deposition chamber.

9. The method of claim 7, wherein the H₂ gas is introduced into the deposition chamber after the SiH₄ is introduced into the deposition chamber.

10. The method of claim 7, further comprising annealing the intermediate device after forming the liner layer of SiO₂.

11. The method of claim 10, wherein the liner layer of SiO₂ is conformally deposited.

12. The method of claim 7, further comprising forming a trench in the substrate between the nFET fins and the pFET fins.

13. The method of claim 12, wherein SiN layer and the liner layer of SiO₂ are formed over the trench.

14. A method of fabricating a semiconductor device, the method comprising:
forming a plurality of fins from a substrate, the fins including nFET fins and pFET fins;
forming a trench between the nFET fins and pFET fins, the trench including one or more fins;
forming a silicon nitride (SiN) layer over the trench, the nFET fins and the pFET fins;
forming a liner layer of SiO₂ over the SiN layer with a non-high density plasma (HDP) process to create an intermediate device; and
depositing with a high density plasma (HDP) process a HDP layer of silicon dioxide (SiO₂) over the trench, the nFET fins and the pFET fins;
wherein the HDP process includes loading the intermediate device into a deposition chamber and introducing hydrogen (H₂) gas and silane (SiH₄) into the deposition chamber, wherein the H₂ gas is not introduced into the deposition chamber before the SiH₄ is introduced into the deposition chamber.

15. The method of claim 14, wherein the one or more fins in the trench are separated from each other by less than 0.1 micrometer to mitigate delamination.

16. The method of claim 14, wherein, the H₂ gas is introduced into the deposition chamber at the same time the SiH₄ is introduced into the deposition chamber.

17. The method of claim 14, wherein the H₂ gas is introduced into the deposition chamber after the SiH₄ is introduced into the deposition chamber.

18. The method of claim 14, wherein the liner layer of SiO₂ is conformally deposited over the SiN layer.

19. The method of claim 18, further comprising annealing the intermediate device after forming the liner layer of SiO₂.
